(19) United States
(12) Patent Application Publication
(10) Pub. No.: US 2022/0157637 A1
(43) Pub. Date: May 19, 2022

(54) DICING DIE BONDING FILM

(71) Applicant: NITTO DENKO CORPORATION, Osaka (JP)

(72) Inventors: Shuto Taniguchi, Osaka (JP); Tomoaki Ichikawa, Osaka (JP)

(73) Assignee: NITTO DENKO CORPORATION, Osaka (JP)

(21) Appl. No.: 17/523,237

(22) Filed: Nov. 10, 2021

(30) Foreign Application Priority Data
Nov. 18, 2020 (JP) 2020-191769
Sep. 1, 2021 (JP) 2021-142373

(51) Int. Cl. H01L 21/683; C09J 9/02; C09J 133/08; C09J 7/22

(52) U.S. Cl. CPC H01L 21/6836; C09J 7/22; C09J 133/08; C09J 9/02

(57) ABSTRACT

A dicing die bonding film according to the present invention includes: a dicing tape including a base layer and an adhesive layer laminated on the base layer; and a die bonding layer laminated on the adhesive layer of the deicing tape; the die bonding layer including a matrix resin, a thiol-group-containing compound, and conductive particles.

### CROSS-REFERENCE TO RELATED APPLICATION

This application claims priority to Japanese Patent Application No. 2020-191769 and Japanese Patent Application No. 2021-142373, the disclosures of which are incorporated herein by reference in their entirety.

### FIELD OF THE INVENTION

The present invention relates to a dicing die bonding film.

### BACKGROUND OF THE INVENTION

In order to improve the electric conductivity and thermal conductivity of a semiconductor chip such as a power semiconductor subjected to a large amount of current and heat in a semiconductor device, it is known that a semiconductor chip with a metal layer is produced using a semiconductor wafer with a metal layer (i.e., a metal-layer-formed semiconductor wafer) having, as the metal layer, a bonding side surface of the semiconductor water to which a substrate is bonded (for example, JP 2015-95550 A).

Meanwhile, it is also known that a dicing die bonding film is used as a member for dicing and bonding a semiconductor chip obtained by the dicing to a substrate (for example, JP 2019-9203 A). The dicing die bonding film includes a dicing tape including a base layer and an adhesive layer laminated on the base layer, and a die bonding layer peelably laminated on the adhesive layer of the dicing tape. In the dicing die bonding film, conductive particles are included in the die bonding layer to thereby produce the conductivity as in the same manner as in bonding by soldering.

### SUMMARY OF THE INVENTION

### Technical Problem

When adhesiveness between the die bonding layer and the metal-layer-formed semiconductor wafer is low, chip flying may occur during dicing. Thus, the die bonding layer is demanded to have an increased adhesiveness to the metal-layer-formed semiconductor wafer.

Nevertheless, no sufficient consideration appears to have been made on increasing the adhesiveness between the die bonding layer and the metal-layer-formed semiconductor wafer.

It is therefore an object of the present invention to provide a dicing die bonding film capable of increasing the adhesiveness between the die bonding layer and the metal-layer-formed semiconductor wafer.

### Solution to Problem

A dicing die bonding film according to the present invention includes: a dicing tape including a base layer and an adhesive layer laminated on the base layer; and a die bonding layer laminated on the adhesive layer of the deicing tape;

the die bonding layer including a matrix resin, a thiol-group-containing compound, and conductive particles.

In the dicing die bonding film, it is preferable that the thiol-group-containing compound be a polyfunctional thiol compound having two or more thiol groups.

In the dicing die bonding film, it is preferable that the die bonding layer include 0.1 mass % or more and 30 mass % or less of the thiol-group-containing compound.

In the dicing die bonding film, it is preferable that the die bonding layer have a peel strength against the metal layer at room temperature of 0.5 N/10 mm or more in a state where the die bonding layer is attached to a metal layer of a silicon wafer, the silicon wafer having one side on which the metal layer is formed.

In the dicing die bonding film, it is preferable that a packing ratio P of the conductive particles in the die bonding layer be 70 mass % or more and 95 mass % or less, and a viscosity of the die bonding layer at 150° C. be 30 kPa·s or more.

### BRIEF DESCRIPTION OF DRAWINGS

FIG. 1 is a cross-sectional view showing a configuration of a dicing die bonding film according to one embodiment of the present invention.

### DETAILED DESCRIPTION OF THE PREFERRED EMBODIMENT

Hereinafter, a description will be given on one embodiment of the present invention.

### [Dicing Die Bonding Film]

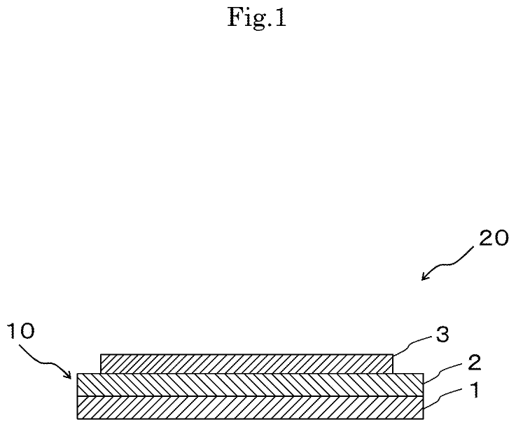

As shown in FIG. 1, a dicing die bonding film 20 according to this embodiment includes a dicing tape 10 including a base layer 1 and an adhesive layer 2 laminated on the base layer 1, and a die bonding layer 3 laminated on the adhesive layer 2 of the dicing tape 10. The dicing die bonding film 20 has a semiconductor wafer attached on the die bonding layer 3. In this embodiment, a semiconductor wafer with a metal layer (hereinafter also referred to as a metal-layer-formed semiconductor wafer) formed on one side thereof (i.e., on the opposite side to a circuit side) is attached on the die bonding layer 3. Specifically, the metal-layer-formed semiconductor wafer is attached to the die bonding layer 3 with the metal layer contacting the die bonding layer 3. The metal-layer-formed semiconductor wafer attached to the dicing die bonding film 20 according to this embodiment is cut into a plurality of semiconductor chips by blade dicing, DBG (dicing before grinding) or SDBG (stealth dicing before grinding), or the like. The die bonding layer 3 is also cut at the time of the cutting of the semiconductor wafer as above. The die bonding layer 3 is cut into pieces each having a size corresponding to the size of each of the plurality of semiconductor chips formed into individual pieces. It is thus possible to obtain a plurality of semiconductor chips each having the die bonding layer 3, more specifically, a plurality of semiconductor chips in each of which a metal layer is attached to the die bonding layer 3. In the metal-layer-formed semiconductor wafer, the metal layer is formed by coating one side of the semiconductor wafer (i.e., the opposite side to a circuit side) with a metal. As such a metal, a noble metal such as gold, silver, or copper is generally used. Examples of the method for coating one side of the semiconductor wafer with the metal include plasma vapor deposition, sputtering, and electron beam deposition. The metal layer is generally formed at a thickness of 1 μm or more and 10 μm or less.

In the dicing die bonding film 20 according to this embodiment, the die bonding layer 3 includes a matrix resin, a thiol-group-containing compound, and conductive particles. The conductive particles herein mean particles having an electric conductivity measured according to JIS K 0130 (2008) of 100 μS/cm or less.

In the dicing die bonding film 20 according to this embodiment, it is important that the die bonding layer 3 includes the thiol-group-containing compound. Inclusion of the thiol-group-containing compound in the die bonding layer 3 enables to increase the adhesiveness between the die bonding layer 3 and the metal layer. Thereby, the dicing die bonding film 20 according to this embodiment can have increased adhesiveness to the metal-layer-formed semiconductor wafer.

The die bonding layer 3 preferably has thermosetting properties. That is, the die bonding film according to this embodiment preferably includes a resin having thermosetting properties as a matrix resin and more preferably further includes a curing agent for the resin having thermosetting properties.

Examples of the resin having thermosetting properties include a thermosetting resin and a thermoplastic resin that has a thermosetting functional group.

Examples of the thermosetting resin include an epoxy resin, a phenol resin, an amino resin, an unsaturated polyester resin, a polyurethane resin, a silicone resin, and a thermosetting polyimide resin. These different thermosetting resins may be individually used, or two or more different resins may be used in combination. Among the above various thermosetting resins, an epoxy resin is preferably used.

Examples of the epoxy resin include the epoxy resins of bisphenol A type, bisphenol F type, bisphenol S type, brominated bisphenol A type, hydrogenated bisphenol A type, bisphenol AF type, biphenyl type, naphthalene type, fluorene type, phenol novolak type, cresol novolak type, ortho-cresol novolak type, trishydroxyphenylmethane type, tetraphenylolethane type, hydantoin type, trisglycidyl isocyanurate type, and glycidyl amine type. Among these, at least one of a bisphenol A type epoxy resin and a cresol novolak type epoxy resin is preferably used, and a bisphenol A type epoxy resin and a cresol novolak type epoxy resin are more preferably used in combination. Examples of the bisphenol A type epoxy resin include an aliphatic modified bisphenol A type epoxy resin.

Examples of the phenol resin as a curing agent for the epoxy resin include a novolak type phenol resin, a resol type phenol resin, a biphenyl type phenol resin, and a polyoxystyrene such as polyparaoxystyrene.

A thermoplastic resin having a thermosetting functional group can also be used as a thermosetting resin. Examples of the thermoplastic resin having a thermosetting functional group include a thermosetting functional group-containing acrylic resin. Examples of the acrylic resin in the thermosetting functional group-containing acrylic resin include an acrylic resin including a monomer unit derived from a (meth)acrylate ester. For the thermoplastic resin having a thermosetting functional group, a curing agent is selected depending on the type of the thermosetting functional group.

The die bonding layer can include a thermoplastic resin as a matrix resin. The thermoplastic resin functions as a binder. Inclusion of the thermoplastic resin in the die bonding layer 3 enables the die bonding layer 3 to have a relatively low elasticity even after being heat-cured. Examples of the thermoplastic resin includes natural rubber, a butyl rubber, an isoprene rubber, a chloroprene rubber, an ethylene-vinyl acetate copolymer, an ethylene-acrylate copolymer, an ethylene-acrylate ester copolymer, a polybutadiene resin, a polycarbonate resin, a thermoplastic polyimide resin, a polyamide resin such as polyamide 6 or polyamide 6,6, a phenoxy resin, an acrylic resin, a saturated polyester resin such as PET or PBT, a polyamide-imide resin, and a fluororesin. These different thermoplastic resins may be individually used, or two or more different resins may be used in combination. As the thermoplastic resin, an acrylic resin is preferable in terms of its small amount of ionic impurities and high thermal resistance allowing the die bonding layer 3 to easily secure connection reliability.

The acrylic resin is preferably a polymer that includes a monomer unit derived from a (meth)acrylate ester as the largest monomer unit by mass ratio. Examples of the (meth)acrylate ester include (meth)acrylate alkyl ester, (meth)acrylate cycloalkyl ester, and (meth)acrylate aryl ester. The acrylic resin may include a monomer unit derived from other component copolymerizable with the (meth)acrylate ester. Examples of the other component include a carboxy group-containing monomer, an acid anhydride monomer, a hydroxy group-containing monomer, a glycidyl group-containing monomer, a sulfonic acid group-containing monomer, a phosphate group-containing monomer, a functional group-containing monomer such as acrylic amid or acrylonitrile, and various multifunctional monomers. The acrylic resin is preferably a carboxyl-containing acrylic rubber.

The thiol-group-containing compound may be a monofunctional thiol compound (a thiol compound having one thiol group (SH)) or may be a multifunctional thiol compound (a thiol compound having two or more thiol groups (SH)), but the multifunctional thiol compound (a thiol compound having two or more thiol groups (SH)) is preferable. Examples of the multifunctional thiol compound include a difunctional thiol compound, a trifunctional thiol compound, a tetrafunctional thiol compound, and a hexafunctional thiol compound. The multifunctional thiol compound having two or more thiol groups (SH) enables to further increase the adhesiveness between the die bonding layer 3 and the metal-layer-formed semiconductor wafer. These kinds of thiol-group-containing compounds may be individually used, or two or more kinds of them may be used in combination.

As the monofunctional thiol compound, any organic compound having one thiol group (SH) can be employed, and examples of the commercially available monofunctional thiol compound include BMPA, EHMP, MBMP, and STMP manufactured by SC Organic Chemical Co., Ltd. As the difunctional thiol compound, any organic compound having two thiol groups (SH) can be employed, and examples of the commercially available difunctional thiol compound include BD1 manufactured by Showa Denko K.K., and EGMP-4 and PXDT manufactured by SC Organic Chemical Co., Ltd. As the trifunctional thiol compound, any organic compound having three thiol groups (SH) can be employed, and examples of the commercially available trifunctional thiol compound include TPMB and NR1 manufactured by Showa Denko K.K., and TMMP, TMMP-LV, TEMPIC, and PEPT manufactured by SC Organic Chemical Co., Ltd. As the tetrafunctional thiol compound, any organic compound having four thiol groups (SH) can be employed, and examples of the commercially available tetrafunctional thiol compound include PE1 manufactured by Showa Denko K.K., PEMP and PEMP-1 manufactured by SC Organic Chemical Co., Ltd., and TS-G and C3TS-G manufactured by Shikoku Chemicals Corporation. As the hexafunctional thiol compound, any organic compound having six thiol groups (SH) can be employed, and examples of the commercially available hexafunctional thiol compound include DPMP manufactured by SC Organic Chemical Co., Ltd.

The die bonding layer 3 includes preferably 0.1 mass % or more and 30 mass % or less of the thiol-group-containing compound. The die bonding layer 3 includes more preferably 0.2 mass % or more and 15 mass % or less, still more preferably 0.3 mass % or more and 4.5 mass % or less, particularly preferably 0.5 mass % or more and 2.0 mass % or less, of the thiol-group-containing compound. Inclusion of the thiol-group-containing compound in the die bonding layer 3 within the above range enables to further increase the adhesiveness between the die bonding layer 3 and the metal-layer formed semiconductor wafer. Thereby, occurrence of chip flying after dicing of the metal-layer-formed semiconductor wafer by using a dicing die bonding film can be further suppressed. The content ratio of the thiol-group-containing compound herein means the content ratio in the composition that forms the die bonding layer 3.

The conductive particles preferably include silver particles. The shape of the silver particles may be, for example, a flake shape, a needle shape, a filament shape, a spherical shape, and a flat shape (including a scale-like shape).

The silver particles have a volume average particle size D₅₀ of preferably 0.01 μm or more, more preferably 0.1 μm or more, particularly preferably 0.5 μm or more. The volume average particle size D₅₀ of the silver particles being 0.01 μm or more allows the silver particles to be relatively easily dispersed in the die bonding layer, and suppresses the surfaces of the silver particles from oxidization which easily occurs when the specific surface area of the silver particles is excessively large, thereby being capable of securing sufficient conductivity of the silver particles. The silver particles having a volume average particle size D₅₀ of 0.1 μm or more can be more easily dispersed in the die bonding layer, and can have better conductivity. The silver particles having a volume average particles size D₅₀ of 0.5 μm or more can be even more easily dispersed in the die bonding layer, and can have even better conductivity. The silver particles have a volume average particle size D₅₀ of preferably 10 μm or less, more preferably 5 μm or less, particularly preferably 1 μm or less. With the volume average particle size D₅₀ of the silver particles being 10 μm or less, the outer surfaces of the silver particles can be molten to the extent sinterable at about a temperature at which the thermosetting resin is cured (for example 200° C.). With the volume average particle size D₅₀ of the silver particles being 5 μm or less, the outer surfaces of the silver particles can be more easily molten to the extent sinterable at about a temperature at which the thermosetting resin is cured. Since the volume average particle size D₅₀ of the silver particles is 1 μm or less, the outer surfaces of the silver particles can be further easily molten to the extent sinterable at about a temperature at which the thermosetting resin is cured. Further, the conductive particles have a volume average particle size D₅₀ of preferably 0.01 μm or more and 10 μm or less, more preferably 0.1 μm or more and 5 μm or less, particularly preferably 0.5 μm or more and 1 μm or less.

The volume average particle sizes D₅₀ of the silver particles can be measured using, for example, a laser diffraction and scattering type particle size measuring apparatus (Microtrac MT3000II series manufactured by MicrotracBEL) on a volume basis.

The silver particles may be silver particles composed of the silver element and other elements (e.g., metal elements) included as inevitable impurity elements, or may be silver particles subjected to surface treatment (for example, silane coupling treatment). Examples of the surface treatment agent for the silver particles include coating agents that are aliphatic acid-based, amine-based, epoxy-based, and the like. Examples of the commercially available silver particles subjected to surface treatment with an aliphatic acid-based coating agent include AG-2-8F manufactured by DOWA Electronics Materials Co., Ltd. The silver particles subjected to surface treatment with an aliphatic acid-based, amine-based, or epoxy-based coating agent may be hereinafter referred to as the silver particles treated with a coating agent. In the die bonding layer according to this embodiment, the silver particles treated with a coating agent are preferably used as the silver particles. Since the use of the silver particles treated with a coating agent as the silver particles can increase affinity for the resin component (i.e., the thermosetting resin and the thermoplastic resin) included therein, the silver particles are easily dispersed in the die bonding layer.

The conductive particles may include nickel particles, copper particles, aluminum particles, carbon black, carbon nanotubes, particles formed by plating the surfaces of core metal particles with a metal such as gold or silver (hereinafter referred to also as plated metal particles), particles formed by coating the surfaces of core resin particles with a metal (hereinafter referred to also as metal-coated resin particles), and the like, other than the silver particles. These kinds of conductive particles may be individually used, or two or more kinds of them may be used in combination.

As the plated metal particles, for example, particles in which nickel particles or copper particles serve as cores and the surfaces of the cores are plated with a metal such as gold or silver can be used. As the metal-coated resin particles, for example, particles in which resin particles serve as cores and the surfaces of the cores are coated with a metal such as nickel or gold can be used. In the case where the die bonding layer according to this embodiment includes conductive particles other than the silver particles, the plated metal particles are preferably used as the conductive particles, and particles in which copper particles serve as cores and the surfaces of the cores are plated with silver (silver-coated copper particles) are preferably used as the plated metal particles. Examples of the commercially available silver-coated copper particles include: particles obtained by coating product name 1200YP (copper particles) manufactured by MITSUI MINING & SMELTING CO., LTD. with 20 mass % of silver particles; particles obtained by coating product name MA-C03K (copper particles) manufactured by MITSUI MINING & SMELTING CO., LTD. with 20 mass % of silver particles; and product name AOP-TCY-2 (EN) manufactured by DOWA Electronics Materials Co., Ltd. In the case where the die bonding layer according to this embodiment includes conductive particles other than the silver particles, the mass % of the silver particles in 100 mass % of the conductive particles is preferably 10 mass % or more and 95 mass % or less, more preferably 20 mass % or more and 90 mass % or less.

The shape of the conductive particles other than the silver particles may be, for example, a flake shape, a needle shape, a filament shape, a spherical shape, and a flat shape (including a scale-like shape). Use of the particles having a spherical shape as the conductive particles other than the silver particles can increase the dispersibility of the conductive particles other than the silver particles in the die bonding layer.

The conductive particles other than the silver particles have a volume average particle size D₅₀ of preferably 0.01 μm or more, more preferably 0.5 μm or more, particularly preferably 1.5 μm or more. The conductive particles other than the silver particles have a volume average particle size D₅₀ of preferably 20 μm or less, more preferably 10 μm or less, particularly preferably 5 μm or less. Further, the conductive particles other than the silver particles have a volume average particle size D₅₀ of preferably 0.01 μm or more and 20 μm or less, more preferably 0.5 μm or more and 10 μm or less, particularly preferably 1.5 μm or more and 5 μm or less. The volume average particle size D₅₀ of the conductive particles other than the silver particles can also be measured in the same manner as for the volume average particle size D₅₀ of the silver particles mentioned above.

The die bonding layer may include a thermosetting catalyst in terms of sufficiently progressing the curing reaction of the resin component or increasing the curing reaction rate. Examples of the thermosetting catalyst include an imidazole-based compound, a triphenylphosphine-based compound, an amine-based compound, and a trihalogenborane-based compound.

In the dicing die bonding film 20 according to this embodiment, the die bonding layer 3 in a state of being attached to a metal layer of a silicon wafer including the metal wafer on one side thereof has a peel strength against the metal layer at room temperature of preferably 0.5 N/10 mm or more, more preferably 0.7 N/10 mm or more. The peel strength against the metal layer at room temperature of 0.5 N/10 mm or more enables to further increase the adhesiveness between the die bonding layer and the metal-layer-formed semiconductor wafer. Thereby, occurrence of chip flying after dicing of the metal-layer-formed semiconductor wafer by using a dicing die bonding film can be further suppressed. The peel strength against the metal layer at room temperature can be 15 N/10 mm or less. The room temperature herein means the temperature at 23±2° C.

The peel strength against the metal layer at room temperature can be measured by a peel test using a tensile tester (product name: AUTOGRAPH AG-X manufactured by Shimadzu Corporation) at room temperature, at a peeling angle of 180°, and at a tensile speed of 300 mm/min. Specifically, the measurement can be performed as follows:

(1) A die bonding layer is laid on a metal layer of a silicon wafer, the metal layer being formed on one side of the silicon wafer (i.e., a metal-layer-formed silicon wafer) to obtain a laminated body. The silicon wafer is a bare wafer.
(2) The laminated body is placed on a hot plate heated to 70° C. The laminated body is placed so as to allow the surface of the metal-layer-formed silicon wafer, which surface does not include a metal layer, to contact the surface.
(3) The laminated body is pressed using a pressure roller (with the roller weight of 2 kg) to attach the metal-layer-formed silicon wafer and the die bonding layer to each other, which is then left to stand on the hot plate for 2 minutes.
(4) The laminated body that has been left to stand is taken from the hot plate, and then left to stand at room temperature (23±2° C.) for 20 minutes to obtain a test body.
(5) A peel test is performed for the test body under the above conditions using the above tensile tester to measure the peel strength against the metal layer at room temperature.

In the dicing die bonding film 20 according to this embodiment, the packing ratio P of the conductive particles in the die bonding layer 3 is preferably 70 mass % or more and 95 mass % or less, and the viscosity of the die bonding layer 3 at 150° C. is preferably 30 kPa·s or more. The packing ratio P falling within the above numerical range and the viscosity of the die bonding layer 3 at 150° C. falling within the above numerical range enable to further increase the adhesiveness between the die bonding layer and the metal-layer-formed semiconductor wafer. Thereby, occurrence of chip flying after dicing of the metal-layer-formed semiconductor wafer by using a dicing die bonding film can be further suppressed. The packing ratio P of the conductive particles in the die bonding layer 3 is more preferably 75 mass % or more, further preferably 80 mass % or more. The packing ratio P of the conductive particles in the die bonding layer 3 is more preferably 90 mass % or less, further preferably 85 mass % or less. The packing ratio of the conductive particles in the die bonding layer 3 herein means the content ratio of the conductive particles in the composition that forms the die bonding layer 3, and, when the composition that forms the die bonding layer 3 includes a catalyst (e.g., methyl ethyl ketone (MEK)), it means the content ratio of the conductive particles in the composition excluding the catalyst. The viscosity of the die bonding layer 3 at 150° C. is more preferably 40 kPa·s or more, further preferably 50 kPa·s or more. The viscosity of the die bonding layer 3 at 150° C. is more preferably 500 kPa·s or less, further preferably 400 kPa·s or less.

The viscosity of the die bonding layer 3 at 150° C. can be evaluated using a rheometer (a rotational rheometer HAAKE MARS manufactured by Thermo Fisher Scientific). Specifically, it can be obtained by reading an indicated value at 150° C. when temperature rises from 30° C. to 180° C. at a temperature rising rate of 10° C./min.

In the dicing die bonding film 20 according to this embodiment, the thickness of the die bonding layer 3 is preferably 5 μm or more, more preferably 10 μm or more, further preferably 20 μm or more. The thickness of the die bonding layer 3 is preferably 150 μm or less, more preferably 100 μm or less, further preferably 80 μm or less. The die bonding layer 3 having a thickness of 150 μm or less can have more improved thermal conductivity. The thickness of the die bonding layer 3 can be obtained by measuring the thickness thereof at any five positions selected at random using a dial gauge (model R-205 manufactured by PEACOCK), followed by arithmetically averaging these thickness values.

The die bonding layer 3 according to this embodiment may include one or more kinds of other components as needed. Examples of the other components include a filler dispersant, a flame retarder, a silane coupling agent, and an ion trapping agent.

The base layer 1 supports the adhesive layer 2, and the die bonding layer 3 laminated on the adhesive layer 2. The base layer 1 includes a resin. Examples of the resin include an olefin-based resin such as polyethylene (PE), polypropylene (PP), or an ethylene-propylene copolymer; a copolymer including ethylene as a monomer component, such as an ethylene-vinyl acetate copolymer (EVA), an ionomer resin, an ethylene-(meth) acrylate copolymer, or an ethylene-(meth)acrylate ester (random or alternate) copolymer; a polyester such as polyethylene terephthalate (PET), polyethylene naphthalene (PEN), or polybutylene terephthalate (PBT); an acrylic resin; polyvinyl chloride (PVC); a polyurethane; a polycarbonate; polyphenylene sulfide (PPS); an amide-based resin such as polyamide or wholly aromatic polyamide (aramid); polyether ether ketone (PEEK); a polyimide; a polyether imide; polyvinylidene chloride; an acrylonitrile butadiene styrene copolymer (ABS); a cellulose-based resin; a silicone resin; and a fluororesin. Among these, polyethylene is preferably included in the base layer 1.

The base layer 1 may include one kind of the aforementioned resins, or may include two or more kinds of the aforementioned resins.

A material of the base layer 1 may be a crosslinked polymer or the like of any of the resins (for example, a plastic film). The plastic film may be used without being stretched, or may be subjected to uniaxial or biaxial stretching as needed for use. According to a resin sheet to which heat shrinkability is imparted by stretching or the like, a contact area between the adhesive layer 2 and the die bonding layer 3 can be reduced by causing the base layer 1 of the resin sheet to heat shrink after dicing, to thereby allow semiconductor chips (semiconductor devices) to be easily collected.

A surface of the base layer 1 may be subjected to a general surface treatment to increase, for example, its adhesiveness to an adjacent layer, or its capability of being secured to the adjacent layer. Examples of the surface treatment include a chemical or physical treatment such as chromic acid treatment, ozone exposure, flame exposure, high-pressure electric shock exposure, or ionized radiation treatment; and coating treatment using a primer.

The base layer 1 has a thickness of preferably 1 μm or more and 1000 μm or less, more preferably 10 μm or more and 500 μm or less, further preferably 20 μm or more and 300 μm or less, particularly preferably 30 μm or more and 200 μm or less. The thickness of the base layer 1 can be obtained using a dial gauge (model R-205 manufactured by PEACOCK), as in the thickness of the die bonding layer 3 as aforementioned.

The base layer 1 may include various additives. Examples of the various additives include a colorant, a filler, a plasticizer, an aging retardant, an antioxidant, a surfactant, and a flame retarder.

An adhesive used for forming the adhesive layer 2 is not particularly limited, and for example a general pressure-sensitive adhesive such as an acrylic adhesive or a rubber adhesive can be used. The pressure-sensitive adhesive is preferably an acrylic adhesive including an acrylic polymer as a base polymer in terms of, for example, securing clean washability of electronic components such as semiconductor wafers or glasses, which should be kept away from contamination, using ultrapure water or an organic solvent such as an alcohol.

Examples of the acrylic polymer include an acrylic polymer that includes, as a monomer component, one or more kinds of a (meth)acrylate alkyl ester and a (meth)acrylate cycloalkyl ester. Examples of the (meth)acrylate alkyl ester can include a linear or branched alkyl ester having a 1-30C, particularly 4-18C alkyl group, such as methyl ester, ethyl ester, propyl ester, isopropyl ester, butyl ester, isobutyl ester, s-butyl ester, t-butyl ester, pentyl ester, isopentyl ester, hexyl ester, heptyl ester, octyl ester, 2-ethylhexyl ester, isooctyl ester, nonyl ester, decyl ester, isodecyl ester, undecyl ester, dodecyl ester, tridecyl ester, tetradecyl ester, hexadecyl ester, octadecyl ester, or eicosyl ester. Examples of the (meth)acrylate cycloalkyl ester can include cyclopentyl ester and cyclohexyl ester. The (meth)acrylate ester means at least one of the acrylate ester or the methacrylate ester, and the term (meth) herein is used in the same way as above throughout the specification.

The acrylic polymer may include a unit corresponding to another monomer component that is copolymerizable with the (meth)acrylate alkyl ester or the (meth)acrylate cycloalkyl ester, as appropriate, for the purpose of improving cohesive force, heat resistance, or the like. Examples of such a monomer component include: a carboxyl group-containing monomer such as acrylate, methacrylate, carboxyethyl (meth)acrylate, carboxypentyl (meth)acrylate, itaconic acid, maleic acid, fumaric acid, or crotonic acid; an acid anhydride monomer such as maleic anhydride or itaconic anhydride; a hydroxy group-containing monomer such as 2-hydroxythyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, or (4-hydroxymethyl cyclohexyl) methyl (meth)acrylate; a sulfonic acid group-containing monomer such as styrenesulfonic acid, arylsulfonic acid, 2-(meth)acrylamide-2-methylpropanesulfonic acid, (meth)acryloyloxynaphthalenesulfonic acid, or sulfopropyl (meth)acrylate; a phosphate group-containing monomer such as 2-hydroxyethyl acryloyl phosphate; acrylamide; and acrylonitrile. One or more kinds of these copolymerizable monomer components can be used. The amount of these copolymerizable monomers in use is preferably 40 mass % or less of the total monomer components.

The acrylic polymer can further include a multifunctional monomer or the like as a copolymerizing monomer component as needed for crosslinking. Examples of such a multifunctional monomer include hexanediol di(meth)acrylate, (poly)ethylene glycol di(meth)acrylate, (poly)propylene glycol di(meth)acrylate, neopentyl glycol di(meth)acrylate, pentaerythritol di(meth)acrylate, tripmethylolpropane tri(meth)acrylate, pentaerythritol tri(meth)acrylate, dip entaerythritol hexa(meth)acrylate, epoxy (meth)acrylate, polyester (meth)acrylate, and urethane (meth)acrylate. One or more kinds of these multifunctional monomers can be used. The amount of these multifunctional monomers in use is preferably 30 mass % or less of the total monomer components in terms of, for example, their adhesion characteristics.

The acrylic polymer can be obtained by polymerizing a single monomer or two or more kinds of monomer mixtures. The polymerization may be performed by any of solution polymerization, emulsion polymerization, bulk polymerization, suspension polymerization, and the like. The acrylic polymer preferably has a small content of low-molecular weight substances in terms of, for example, preventing a clean adherend from contamination. In this regard, the number average molecular weight of the acrylic polymer is preferably 300,000 or more, more preferably about 400,000 to 3,000,000.

An external crosslinking agent can be appropriately added to the adhesive, in order to increase the number average molecular weight of the acrylic polymer or the like, which is the base polymer of the adhesive. Specific examples of the external crosslinking method include a method which includes adding a crosslinking agent such as a polyisocyanate compound, an epoxy compound, an aziridine compound, or a melamine-based crosslinking agent to the adhesive to cause a reaction. In the case where the external crosslinking agent is used, the amount of the external crosslinking agent in use is determined as appropriate, in consideration of the balance with the amount of the base polymer to be crosslinked and its intended use as the adhesive. Generally, the amount of the external crosslinking agent mixed with the base polymer is preferably about 5 parts by mass or less, more preferably 0.1 to 5 parts by mass based on 100 parts by mass of the base polymer.

In addition to the aforementioned components, the adhesive may include additives such as any known tackifier and aging retardant as appropriate.

The adhesive layer 2 can be formed of a radiation-curable adhesive. The radiation-curable adhesive can easily reduce its pressure-sensitive adhesiveness by being irradiated with radiation such as ultraviolet rays to increase the degree of crosslinking. That is, the adhesive layer 2 formed of the radiation-curable adhesive allows the die bonding layer 3 to be in sufficient contact with the adhesive layer 2 without being subjected to radiation irradiation before dicing, and reduces its pressure-sensitive adhesiveness by being subjected to radiation irradiation after dicing so that semiconductor chips (semiconductor devices) can be easily picked up or collected.

The radiation-curable adhesive is not particularly limited, and can be any adhesive as long as it has a radiation-curable functional group of a carbon-carbon double bond or the like, and exhibits pressure-sensitive adhesiveness. Examples of the radiation-curable adhesive include an additive-type radiation-curable adhesive in which a radiation-curable monomer component or oligomer component is mixed with a general pressure-sensitive adhesive such as an acrylic adhesive or a rubber adhesive.

Examples of the radiation-curable monomer component include urethane (meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxy penta(meth)acrylate, dipentaerythritol hexa(meth)acrylate, and 1,4-butanediol di(meth)acrylate. Examples of the radiation-curable oligomer component include a urethane-based oligomer, a polyether-based oligomer, a polyester-based oligomer, a polycarbonate-based oligomer, a polybutadiene-based oligomer, and various other oligomers, and any of these oligomers having a molecular weight of about 100 to 30,000 is preferable. The mixing amount of the radiation-curable monomer component or the radiation-curable oligomer component is preferably such an amount as to allow the adhesive layer 2 to appropriately reduce its pressure-sensitive adhesiveness after radiation irradiation. Generally, the mixing amount of the radiation-curable monomer component or the radiation-curable oligomer component is, for example, preferably 5 to 500 parts by mass, more preferably 40 to 150 parts by mass, based on the 100 parts by mass of the base polymer such as an acrylic polymer constituting the adhesive.

In addition to the additive-type radiation-curable adhesives mentioned above, the radiation-curable adhesive can be an internally provided radiation-curable adhesive in which a polymer having a carbon-carbon double bond in a side chain or the main chain of the polymer or at a terminal of the main chain is used as the base polymer. The internally provided radiation-curable adhesive does not need to include an oligomer component or the like, which is a low-molecular component, or includes a relatively small content of the oligomer component or the like. Thus, the use of the internally provided radiation-curable adhesive suppresses the oligomer component or the like from migrating within the adhesive layer 2 over time. As a result, the adhesive layer 2 can have a relatively stable layer structure.

The base polymer having the carbon-carbon double bond is not particularly limited as long as it has a carbon-carbon double bond and has pressure-sensitive adhesiveness. Such a base polymer preferably has an acrylic polymer as the basic skeleton. Examples of the basic skeleton of the acrylic polymer include the aforementioned acrylic polymers.

A method for introducing the carbon-carbon double bond into the acrylic polymer is not particularly limited and various methods can be employed, but when adopting a method in which the carbon-carbon double bond is introduced in a polymer side chain, molecular design can be easily made. Examples of the method include a method in which a monomer having a functional group is in advance caused to copolymerize with the acrylic polymer, followed by subjecting a compound having the carbon-carbon double bond and a functional group that can react with the functional group of the monomer to a condensation reaction or an addition reaction in the state where the carbon-carbon double bond is kept radiation-curable.

Examples of the combination of the functional groups include: a carboxylic acid group and an epoxy group, a carboxylic acid group and an aziridinyl group, and a hydroxy group and an isocyanate group. Among these combinations of the functional groups, a combination of a hydroxy group and an isocyanate group is preferable in terms of easy reaction tracking. In these combinations of the functional groups, any of the functional groups can be present on any side of the acrylic polymer and the compound having the carbon-carbon double bond, as long as the combination of the functional groups generates an acrylic polymer having the carbon-carbon double bond. In the case of the aforementioned preferable combination, however, it is preferable that the acrylic polymer have a hydroxy group and the compound having the carbon-carbon double bond have an isocyanate group. In this case, examples of the isocyanate compound having the carbon-carbon double bond include methacryloyl isocyanate, 2-methacryloyloxyethyl isocyanate, and misopropenyl-α,α-dimethylbenzyl isocyanate. Examples of the acrylic polymer include a polymer formed by copolymerizing an ether-based compound or the like such as the aforementioned hydroxy group-containing monomer, 2-hydroxyethyl vinyl ether, 4-hydroxybutyl vinyl ether, or diethylene glycol monovinyl ether.

In the internally provided radiation-curable adhesive, the base polymer having the carbon-carbon double bond (in particular an acrylic polymer) may be individually used, but the radiation-curable monomer component or the radiation-curable oligomer component can be added in such an amount as not to impair the characteristics of the adhesive. The radiation-curable oligomer component or the like is included generally in the range of 30 parts or less by mass, preferably in the range of 1 to 10 parts by mass, based on 100 parts by mass of the base polymer.

The radiation-curable adhesive includes a photopolymerization initiator in the case of being cured by, for example, ultraviolet rays. Examples of the photopolymerization initiator include an α-ketol-based compound such as 4-(2-hydroxyethoxy)phenyl(2-hydroxy-2-propyl) ketone, α-hydroxy-α,α′-dimethylacetophenone, 2-methyl-hydroxypropiophenone, or 1-hydroxycyclohexyl phenyl ketone; an acetophenone-based compound such as methoxyacetophenone, 2,2-dimethoxy-2-phenylacetophenone, 2,2-diethoxyacetophenone, or 2-methyl-1-[4-(methylthio)-phenyl]-2-morpholinopropane-1; an benzoin ether-based compound such as benzoin ethyl ether, benzoin isopropyl ether, or anisoin methyl ether; a ketal-based compound such as benzil dimethylketal; an aromatic sulfonyl chloride-based compound such as 2-naphthalene sulfonyl chloride; a photoactive oxime-based compound such as 1-phenone-1,1-propanedione-2-(o-ethoxycarbonyl)oxime; a benzophenone-based compound such as benzophenone, benzoyl benzoic acid, or 3,3′-dimethyl-4-metoxybenzophenone; a thioxanthone-based compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, or 2,4-diisopropylthioxanthone; camphorquinone; halogenated ketone; acylphosphine oxide; and acylphosphonate. The mixing amount of the photopolymerization initiator is, for example, 0.05 to 20 parts by mass based on 100 parts by mass of the base polymer such as an acrylic polymer constituting the adhesive.

Examples of the radiation-curable adhesive include a rubber or acrylic adhesive disclosed in JP S60-196956 A, which includes: a photopolymerizable compound such as an addition polymerizable compound having two or more unsaturated bonds or alkoxysilane having an epoxy group; and a photopolymerization initiator such as a carbonyl compound, an organic sulfur compound, a peroxide, amine, or an onium salt-based compound.

In the case where curing inhibition by oxygen occurs at the time of radiation irradiation, it is desirable to keep the surface of the radiation-curable adhesive layer 2 away from oxygen (air) using some method. For example, the method can be performed by covering the surface of the adhesive layer 2 with a separator, or by irradiating the surface of the adhesive layer 2 with radiation such as ultraviolet rays in a nitrogen gas atmosphere.

The thickness of the adhesive layer 2 is not particularly limited, but is preferably 1 to 50 μm, more preferably 2 to 30 μm, further preferably 5 to 25 μm, in terms of both preventing chipping of a chip cutting surface and achieving the capability of enabling the die bonding layer 3 to be secured to the adhesive layer 2 and kept in the secured state.

The matters disclosed herein include the following:

(1) A dicing die bonding film according to the present invention includes: a dicing tape including a base layer and an adhesive layer laminated on the base layer; and a die bonding layer laminated on the adhesive layer of the deicing tape;

the die bonding layer including a matrix resin, a thiol-group-containing compound, and conductive particles.

According to such a configuration, the adhesiveness between the die bonding layer and the metal-layer-formed semiconductor wafer can be increased.

(2) In the dicing die bonding film of (1) above, the thiol-group-containing compound is a polyfunctional thiol compound having two or more thiol groups.

According to such a configuration, the adhesiveness between the die bonding layer and the metal-layer-formed semiconductor wafer can be further increased.

(3) In the dicing die bonding film of (1) or (2) above, the die bonding layer includes 0.1 mass % or more and 30 mass % or less of the thiol-group-containing compound.

According to such a configuration, the adhesiveness between the die bonding layer and the metal-layer-formed semiconductor wafer can be further increased.

(4) In the dicing die bonding film of any one of (1) to (3) above, the die bonding layer has a peel strength against the metal layer at room temperature of 0.5 N/10 mm or more in a state where the die bonding layer is attached to a metal layer of a silicon wafer, the silicon wafer having one side on which the metal layer is formed.

(5) In the dicing die bonding film of any one of (1) to (4) above, the die bonding layer has a peel strength against the metal layer at room temperature of 0.7 N/10 mm or more in a state where the die bonding layer is attached to a metal layer of a silicon wafer, the silicon wafer having one side on which the metal layer is formed.

(6) In the dicing die bonding film of (4) or (5) above, the die bonding layer has a peel strength against the metal layer at room temperature of 15 N/10 mm or more in a state where the die bonding layer is attached to a metal layer of a silicon wafer, the silicon wafer having one side on which the metal layer is formed.

According to such a configuration, the adhesiveness between the die bonding layer and the metal-layer-formed semiconductor wafer can be further increased.

(7) In the dicing die bonding film of any one of (1) to (6) above, a packing ratio P of the conductive particles in the die bonding layer is 70 mass % or more and 95 mass % or less, and

a viscosity of the die bonding layer at 150° C. is 30 kPa·s or more.

(8) In the dicing die bonding film of any one of (1) to (6) above, a packing ratio P of the conductive particles in the die bonding layer is 70 mass % or more and 95 mass % or less, and

a viscosity of the die bonding layer at 150° C. is 40 kPa·s or more.

(9) In the dicing die bonding film of any one of (1) to (6) above, a packing ratio P of the conductive particles in the die bonding layer is 70 mass % or more and 95 mass % or less, and

a viscosity of the die bonding layer at 150° C. is 50 kPa·s or more.

(10) In the dicing die bonding film of any one of (7) to (9), a packing ratio P of the conductive particles in the die bonding layer is 70 mass % or more and 95 mass % or less, and

a viscosity of the die bonding layer at 150° C. is 500 kPa·s or less.

(11) In the dicing die bonding film of any one of (7) to (9), a packing ratio P of the conductive particles in the die bonding layer is 70 mass % or more and 95 mass % or less, and

a viscosity of the die bonding layer at 150° C. is 400 kPa·s or less.

According to such a configuration, the adhesiveness between the die bonding layer and the metal-layer-formed semiconductor wafer can be further increased.

The dicing die bonding film according to the present invention is not limited to the aforementioned embodiment. The dicing die bonding film according to the present invention is not limited by the aforementioned operational advantages, either. Various modifications can be made for the dicing die bonding film according to the present invention without departing from the gist of the present invention.

### EXAMPLES

Hereinafter, the present invention will be more specifically described by way of examples. The following examples are provided for more specifically describing the present invention, and do not intend to limit the scope of the present invention.

### Example 1

A mixture of materials having the respective mass ratios shown in the column “Example 1” of Table 1 below was stirred and mixed using a hybrid mixer (product name: HM-500 manufactured by KEYENCE CORPORATION) in the “stirring mode” to prepare a varnish. The stirring and mixing using the hybrid mixer was performed by two steps. Specifically, first, a primary mixture including thermosetting resins (a phenol resin, a solid epoxy resin, and a liquid epoxy resin), conductive particles (silver-coated copper particles and silver particles), and a thiol-group-containing compound was stirred and mixed for three minutes (i.e., primary stirring), and then a thermoplastic resin (an acrylic resin solution), a catalyst, and a solvent were added to the primary mixture and further stirred and mixed for 6 minutes (i.e., secondary stirring). The varnish was applied to one side of a release treatment film (product name: MRA50, with a thickness of 50 μm, manufactured by Mitsubishi Chemical Corporation), followed by being allowed to dry at 100° C. for 2 minutes to obtain a die bonding layer having a thickness of 30 μm. The materials shown in Table 1 below are as follows:

Phenol Resin

MEHC-7851S (biphenyl type phenol resin, phenol equivalent of 209 g/eq), manufactured by MEIWA PLASTIC INDUSTRIES, LTD.

Solid Epoxy Resin

KI-3000-4 (cresol novolak type multifunctional epoxy resin, epoxy equivalent of 200 g/eq), manufactured by Nippon Steel & Sumikin Chemical Co., Ltd.

Liquid Epoxy Resin

EXA-4816 (aliphatic modified bisphenol A type epoxy resin (difunctional type), epoxy equivalent of 403 g/eq), manufactured by DIC Corporation

Silver (Ag)-Coated Copper (Cu) Particles

1200YP manufactured by MITSUI MINING & SMELTING CO., LTD. coated with 10 mass % of silver particles (subjected to surface treatment with an epoxy-based coating agent; the particles have a flat shape, a volume average particle size D₅₀ of 3.5 μm, and an aspect ratio of 10)

Silver (Ag) Particles

SPH02J (aggregate nano-Ag particles; irregular shape; the aggregates have a volume average particle size D₅₀ of 1.8 μm) manufactured by Mitsui Mining & Smelting Co., Ltd.

Thiol-Group-Containing Compound

PEMP (a tetrafunctional thiol compound) manufactured by SC Organic Chemical Co., Ltd.

Acrylic Resin Solution

TEISANRESIN SG-70L (including MEK and toluene as solvents, solid content of 12.5%, glass transition temperature of −13° C., mass-average molecular weight of 900,000, acid value of 5 mg/KOH, carboxyl group-containing acrylic copolymer), manufactured by Nagase ChemteX Corporation

Catalyst

TPP-MK (tetraphenylphosphonium tetra(4-methylphenyl)borate), manufactured by HOKKO CHEMICAL INDUSTRY CO., LTD.

Solvent

Methyl ethyl ketone (MEK)

### Example 2

A die bonding layer according to Example 2 was obtained in the same manner as in Example 1, except that PEPT (a trifunctional thiol compound) manufactured by SC Organic Chemical Co., Ltd. was employed as the thiol-group-containing compound. Table 1 below shows the respective mass ratios of materials included in the varnish used for forming the die bonding layer of Example 2.

### Example 3

A die bonding layer according to Example 3 was obtained in the same manner as in Example 1, except that EGMP-4 (a difunctional thiol compound) manufactured by SC Organic Chemical Co., Ltd. was employed as the thiol-group-containing compound. Table 1 below shows the respective mass ratios of materials included in the varnish used for forming the die bonding layer of Example 3.

### Example 4

A die bonding layer according to Example 4 was obtained in the same manner as in Example 1, except that DPMP (a hexafunctional thiol compound) manufactured by SC Organic Chemical Co., Ltd. was employed as the thiol-group-containing compound. Table 1 below shows the respective mass ratios of materials included in the varnish used for forming the die bonding layer of Example 4.

### Example 5

A die bonding layer according to Example 5 was obtained in the same manner as in Example 1, except that TMMP (a trifunctional thiol compound) manufactured by SC Organic Chemical Co., Ltd. was employed as the thiol-group-containing compound; methyl isobutyl ketone (MIBK) as a solvent and KBE-846 (bis(triethoxysilylpropyl)tetrasulfide) manufactured by Shin-Etsu Chemical Co., Ltd. as a coupling agent were added to the primary mixture and then subjected to the secondary stirring; and the respective mass ratios of the materials included in the varnish were employed as shown in Table 1 below.

### Example 6

A die bonding layer according to Example 6 was obtained in the same manner as in Example 1, except that TMMP (a trifunctional thiol compound) manufactured by SC Organic Chemical Co., Ltd. was employed as the thiol-group-containing compound; methyl isobutyl ketone (MIBK) as a solvent and KBE-846 (bis(triethoxysilylpropyl)tetrasulfide) manufactured by Shin-Etsu Chemical Co., Ltd. as a coupling agent were added to the primary mixture and then subjected to the secondary stirring; and the respective mass ratios of the materials included in the varnish were employed as shown in Table 1 below.

### Comparative Example 1

A die bonding layer according to Comparative Example 1 was obtained in the same manner as in Example 1, except that TMMP (a trifunctional thiol compound) manufactured by SC Organic Chemical Co., Ltd. was employed as the thiol-group-containing compound; methyl isobutyl ketone (MIBK) as a solvent and KBE-846 (bis(triethoxysilylpropyl)tetrasulfide) manufactured by Shin-Etsu Chemical Co., Ltd. as a coupling agent were added to the primary mixture and then subjected to the secondary stirring; and the respective mass ratios of the materials included in the varnish were employed as shown in Table 1 below.

### Comparative Example 2

A die bonding layer according to Comparative Example 2 was obtained in the same manner as in Example 1, except that the thiol-group-containing compound was not added; methyl isobutyl ketone (MIBK) as a solvent and KBE-846 (bis(triethoxysilylpropyl)tetrasulfide) manufactured by Shin-Etsu Chemical Co., Ltd. as a coupling agent were added to the primary mixture and then subjected to the secondary stirring; and the respective mass ratios of the materials included in the varnish were employed as shown in Table 1 below.

TABLE 1

| | Unit | Ex. 1 | Ex. 2 | Ex. 3 | Ex. 4 |
|---|---|---|---|---|---|
| Phenol resin | Mass parts | 3.51 | 3.51 | 3.51 | 3.51 |
| Solid epoxy resin | Mass parts | 2.83 | 2.83 | 2.83 | 2.83 |
| Liquid epoxy resin | Mass parts | 1.21 | 1.21 | 1.21 | 1.21 |
| Ag-coated Cu particles | Mass parts | 35.69 | 35.69 | 35.69 | 35.69 |
| Ag particles | Mass parts | 11.27 | 11.27 | 11.27 | 11.27 |
| Thiol-group-containing | Mass parts | 0.59 | 0.59 | 0.59 | 0.59 |
| compound | | | | | |
| MIBK | Mass parts | — | — | — | — |
| Acrylic resin solution | Mass parts | 25.90 | 25.90 | 25.90 | 25.90 |
| Coupling agent | Mass parts | — | — | — | — |
| Catalyst | Mass parts | 0.01 | 0.01 | 0.01 | 0.01 |
| MEK | Mass parts | 18.99 | 18.99 | 18.99 | 18.99 |
| Total mass parts | | 100.00 | 100.00 | 100.00 | 100.00 |
| | Unit | Ex. 5 | Ex. 6 | C. Ex. 1 | C. Ex. 2 |
| Phenol resin | Mass parts | 3.44 | 3.38 | 3.29 | 3.60 |
| Solid epoxy resin | Mass parts | 2.77 | 2.70 | 2.65 | 2.91 |
| Liquid epoxy resin | Mass parts | 1.18 | 1.16 | 1.13 | 1.24 |
| Ag-coated Cu particles | Mass parts | 34.90 | 34.26 | 33.35 | 35.48 |
| Ag particles | Mass parts | 11.03 | 10.82 | 10.54 | 11.20 |
| Thiol-group-containing | Mass parts | 0.46 | 0.99 | 2.94 | — |
| compound | | | | | |
| MIBK | Mass parts | 1.69 | 1.66 | 1.61 | 1.77 |
| Acrylic resin solution | Mass parts | 25.33 | 24.86 | 24.21 | 26.62 |
| Coupling agent | Mass parts | 0.28 | 0.27 | 0.26 | 0.29 |
| Catalyst | Mass parts | 0.01 | 0.01 | 0.01 | 0.01 |
| MEK | Mass parts | 18.91 | 19.89 | 20.01 | 16.86 |

| | | | | |
|---|---|---|---|---|
| Total mass parts | 100.00 | 100.00 | 100.00 | 100.00 |

### <Viscosity of the Die Bonding Layer at 150° C.>

The viscosity of the die bonding layer according to each of Examples at 150° C. was evaluated using a rheometer (a rotational rheometer HAAKE MARS manufactured by Thermo Fisher Scientific). Specifically, it was obtained by reading an indicated value at 150° C. when temperature rises from 30° C. to 180° C. at a temperature rising rate of 10° C./min. The viscosity at 150° C. obtained for the die bonding layer according to each of Examples is shown in Table 2 below.

<Evaluation of the Shape Retention Properties (Film Formability into Sheet) of the Die Bonding Layer>

The shape retention properties of the die bonding layer were evaluated. Specifically, evaluation was made based on visual observation to find formation or no-formation of a sheet-like film when the varnish according to each of Examples was applied to one side of a release treatment film using an applicator. The varnish that sufficiently formed a sheet-like film (i.e., its sheet-like state was maintained when the release treatment film applied with the varnish was tilted) was evaluated as “good”, and the varnish that could not form a sheet-like film (i.e., its sheet-like state could not be maintained when the release treatment film applied with the varnish was tilted) was evaluated as “poor”. The shape retention properties of the die bonding layer evaluated for the die bonding layer according to each of Examples are shown in Table 2 below.

### <Peel Strength Against the Metal Layer at Room Temperature>

The peel strength against a metal layer of a silicon wafer having the metal layer formed on one side (i.e., a metal-layer-formed bare wafer; the metal layer is formed by silver plating) at room temperature (23±2° C.) was measured for the die bonding layer according to each of Examples and Comparative Examples. The peel strength against the metal-layer-formed bare wafer at room temperature was measured by a peel test using a tensile tester (product name: AUTOGRAPH AG-X manufactured by Shimadzu Corporation) at room temperature, at a peeling angle of 180°, and at a tensile speed of 300 mm/min. Specifically, the measurement was performed as follows:

(1) A die bonding layer is laid on a surface of a metal-layer-formed bare wafer, on which surface the metal layer is formed, to obtain a laminated body.
(2) The laminated body is placed on a hot plate heated to 70° C. The laminated body is placed so as to allow the surface of the silicon wafer, on which no metal layer is formed, to contact the surface of the hot plate.
(3) The laminated body is pressed using a pressure roller (with the roller weight of 2 kg) to attach the metal-layer-formed bare wafer and the die bonding layer to each other, which is then left to stand on the hot plate for 2 minutes.
(4) The laminated body that has been left to stand is taken from the hot plate, and then left to stand at room temperature (23±2° C.) for 20 minutes to obtain a test body.
(5) A peel test is performed for the test body under the above conditions using the above tensile tester to measure the peel strength against the metal layer at room temperature. The peel strength against the metal-layer-formed bare wafer obtained for the die bonding layer according each of Examples and Comparative Examples is shown in Table 2 below.

### <Separation Resistance During Dicing>

Separation resistance during dicing was evaluated using a dicing die bonding film in which a die bonding layer was laminated on an adhesive layer of a dicing tape and a metal-layer-formed bare wafer (the metal layer is formed by silver plating). Specifically, the evaluation was conducted with the following steps:

(1) A metal-layer-formed bare wafer having a thickness of 100 μm and a dimeter of 8 inches (200 mm) is attached to the die bonding layer while being in pressing contact therewith using a pressing device (pressure roller). The metal-layer-formed bare wafer is attached to the die bonding layer while the metal layer is in pressing contact with the die boding layer.
(2) The die bonding layer and the metal-layer-formed bare wafer were subjected to blade dicing using a fully automatic dicing saw (FULLY AUTOMATIC DICING SAW, DFD6361 manufactured by DISCO Corporation), at a spindle rotation of 45000 rpm (min⁻¹), a feeding speed of 30 mm/s, and a pitch of 5 mm, to obtain a plurality of die bonding layers each having a metal-layer-formed bare chip laminated thereon. Separation resistance during dicing is judged to be “good” if there finds no metal-layer-formed bare chip separated from the die bonding layer at a practically problematic level, and is judged to be “poor” if there finds any metal-layer-formed bare chip separated (coming off) from the die bonding layer at a practically problematic level.

The adhesive layer, the dicing tape, and the dicing die bonding film were prepared as follows.

### (Preparation of the Adhesive Layer)

### Synthesizing the Acrylic Polymer

The materials below were put into a reaction vessel including a cooling pipe, a nitrogen introducing pipe, a thermometer, and a stirrer so as to have a monomer concentration of about 55 mass %, followed by being subjected to polymerization reaction under nitrogen gas flow at 60° C. for 10 hours. An acrylic polymer intermediate was thereby synthesized.
2-ethylhexyl acrylate (2HEA): 100 mass parts
2-hydroxyethyl acrylate (HEA): 20 mass parts
Polymerization initiator: Appropriate amount
Polymerization solvent: Toluene

Under the presence of dibutyltin dilaurate (0.1 mass part), 100 mass parts of the synthesized acrylic polymer intermediate and 1.4 mass parts of 2-methacryloyloxyethyl isocyanate (MOI) were subjected to addition reaction in air flow at 50° C. for 60 hours to synthesize an acrylic polymer.

### Preparing the Adhesive Layer

(1) A solution including the materials below is obtained, and toluene is appropriately added to the solution to thereby prepare an adhesive solution having a viscosity of 500 mPa·s:
Synthesized acrylic polymer: 100 mass parts
Polyisocianate compound
(Product name “CORONATE L”, manufactured by Nippon Polyurethane Industry Co., Ltd.): 1.1 mass part
Photopolymerization initiator
(Product name “Irgacure 184” manufactured by Ciba Specialty Chemicals): 3 mass parts
   (2) A PET film is prepared as a release sheet. The adhesive solution prepared as above is applied to one side of the release sheet using an applicator. The one side of the release sheet (PET-based film) is subjected to silicone treatment as release treatment. After the application, it is subjected to drying treatment by heating at 120° C. for 2 minutes to prepare an adhesive layer having a thickness of 30 μm on the release sheet.

### Preparation of the Dicing Tape and the Dicing Die Bonding Film

### Preparing the Dicing Tape

A support base composed of a polyethylene film having a thickness of 80 μm was attached to an exposed surface of the adhesive layer prepared on the release sheet using a laminator at room temperature to prepare a dicing tape. A portion of the adhesive layer of the dicing tape to which a metal-layer-formed bare wafer having a diameter of 8 inches was to be attached was irradiated with ultraviolet rays having an intensity of 300 mJ/cm² to ultraviolet-cure the portion.

### Preparing the Dicing Die Bonding Film

A die bonding layer was arranged on the ultraviolet-cured adhesive layer of the dicing tape so as to be in contact with a surface of the adhesive layer opposite to the surface on which the release sheet was laminated. Then, the die bonding layer and the dicing tape were fed through a laminator at a speed of 0.8 mm/min to attach the die bonding layer to the dicing tape, followed by removing the release sheet to prepare a dicing die bonding film in which the die bonding layer was laminated on the dicing tape.

The separation resistance during dicing evaluated for the die bonding layer according to each of Examples and Comparative Examples is shown in Table 2 below.

TABLE 2

| | Ex. 1 | Ex. 2 | Ex. 3 | Ex. 4 |
|---|---|---|---|---|
| Packing ratio of conductive | 80.5 | 80.5 | 80.5 | 80.5 |
| particles [wt %] | | | | |
| Type of thiol-group- | PEMP | PEPT | EGMP-4 | DPMP |
| containing compound | (tetrafunctional) | (trifunctional) | (difunctional) | (hexafunctional) |
| Addition amount of thiol- | 1.0 | 1.0 | 1.0 | 1.0 |
| group- containing compound | | | | |
| [wt %] | | | | |
| Shape retention properties | Good | Good | Good | Good |
| of die bonding layer | | | | |
| Viscosity at 150° C. [kPa] | 56 | 279 | 54 | 208 |
| Peel strength at room | 8.9 | 7.5 | 6.0 | 7.5 |
| temperature [N/10 mm] | | | | |
| Separation resistance during | Good | Good | Good | Good |
| dicing | | | | |

| | Ex. 5 | Ex. 6 | C. Ex. 1 | C. Ex. 2 |
|---|---|---|---|---|
| Packing ratio of conductive | 80.5 | 80.5 | 80.5 | 80.0 |
| particles [wt %] | | | | |
| Type of thiol-group- | TMMP | TMMP | TMMP | — |
| containing compound | (trifunctional) | (trifunctional) | (trifunctional) | |
| Addition amount of thiol- | 0.8 | 1.8 | 5.1 | — |
| group-containing compound | | | | |
| [wt %] | | | | |
| Shape retention properties | Good | Good | Poor | Good |
| of die bonding layer | | | | |
| Viscosity at 150° C. [kPa] | 241 | 75 | 15 | 730 |
| Peel strength at room | 0.8 | 3.2 | 7.0 | 0.05 |
| temperature [N/10 mm] | | | | |
| Separation resistance during | Good | Good | Poor | Poor |
| dicing | | | | |

It is found from Table 2 that the separation resistance during dicing for the die bonding layer according to each of Examples was evaluated as “good”, while the separation resistance during dicing for the die bonding layer according to each of Comparative Examples was evaluated as “poor”. It is found from these results that the die bonding layer that includes a matrix resin, a thiol-group-containing compound, and conductive particles can suppress occurrence of chip flying during dicing in the state where a die bonding layer is attached to a metal-layer-formed semiconductor chip.

### REFERENCE SIGNS LIST

1: Base layer
2: Adhesive layer
3: Die bonding layer
10: Dicing tape
20: Dicing die bonding film

What is claimed is:

1. A dicing die bonding film comprising:
a dicing tape comprising a base layer and an adhesive layer laminated on the base layer; and
a die bonding layer laminated on the adhesive layer of the deicing tape;
the die bonding layer comprising a matrix resin, a thiol-group-containing compound, and conductive particles.

2. The dicing die bonding film according to claim 1, wherein
the thiol-group-containing compound is a polyfunctional thiol compound having two or more thiol groups.

3. The dicing die bonding film according to claim 1, wherein
the die bonding layer comprises 0.1 mass % or more and 30 mass % or less of the thiol-group-containing compound.

4. The dicing die bonding film according to claim 1, wherein
the die bonding layer has a peel strength against the metal layer at room temperature of 0.5 N/10 mm or more in a state where the die bonding layer is attached to a metal layer of a silicon wafer, the silicon wafer having one side on which the metal layer is formed.

5. The dicing die bonding film according to claim 1, wherein
a packing ratio P of the conductive particles in the die bonding layer is 70 mass % or more and 95 mass % or less, and
a viscosity of the die bonding layer at 150° C. is 30 kPa·s or more.
